(19) United States
(12) Patent Application Publication
(10) Pub. No.: US 2023/0257885 A1
(43) Pub. Date: Aug. 17, 2023

(54) COATED SUBSTRATES AND METHODS FOR THE PREPARATION THEREOF

(71) Applicant: National Research Council of Canada, Ottawa (CA)

(72) Inventors: Dongfang Yang, London (CA); Mihnea Ioan Ionescu, London (CA); Minh Tan Ton-That, Montreal (CA); Karen Stoeffler, Montreal (CA)

(21) Appl. No.: 18/016,237

(22) PCT Filed: Jul. 22, 2021
(86) PCT No.: PCT/CA2021/051020

§ 371 Date: Jan. 13, 2023

Related U.S. Application Data
(60) Provisional application No. 63/054,884, filed on Jul. 22, 2020.

(51) Int. Cl. C23C 28/04; C23C 14/35; C23C 16/50; C23C 14/34; C23C 14/00; C23C 16/32; C23C 16/02; C23C 14/02

(52) U.S. Cl. CPC C23C 28/04; C23C 14/352; C23C 16/50; C23C 14/3464; C23C 14/0036; C23C 16/325; C23C 16/0227; C23C 14/021

(57) ABSTRACT

The present application relates to methods of preparing a coated substrate and coated substrates which can be optionally prepared from such methods. The methods comprise depositing on the substrate a single abrasion resistant layer by magnetron sputtering or depositing on the substrate a dual layer comprising a first abrasion resistant layer deposited by magnetron sputtering and a second abrasion resistant layer deposited by plasma-enhanced chemical vapor deposition.

### CROSS REFERENCE

The present application claims priority to U.S. Provisional Patent Application No. 63/054,884 entitled “Coated Substrates and methods for the Preparation Thereof”, filed Jul. 22, 2020, the contents of which are incorporated by reference herein.

### FIELD

The present application relates to coated substrates and methods for the preparation thereof. The methods can comprise depositing on the substrate, a single layer abrasion resistant layer by magnetron sputtering or a dual layer in which a first abrasion resistant layer is deposited by magnetron sputtering and a second abrasion resistant layer is deposited by plasma-enhanced chemical vapor deposition.

### BACKGROUND

Current automotive glazings are typically based on tempered glass or on laminated glass. It is estimated that the replacement of glass by plastics in automotive glazing could allow for an about 50% reduction of the total glazing weight, due to the low density of plastics (about 1,200 kg/m³) compared to glass (about 2,500 kg/m³). For each passenger vehicle, this would result in significant weight reduction (about 17 kg, i.e. about 1.5% of the total vehicle weight), translating into a potential fuel consumption reduction (about 14 L per year, i.e. about 1.1% fuel economy) and reduced greenhouse gas (GHG) emissions (about 34 kg CO₂ per year). Taking into account the size of the automotive fleet (currently about 22 million registered passenger vehicles in Canada and about 255 million in the US), plastic glazings may have the potential to reduce CO₂ emissions by about 17.5 Mt/year in North America (about 1.4 Mt/year in Canada) assuming an average vehicle weight of about 1,150 kg, average mileage of about 19,000 km/year, a weight savings of about 50% of glazing and an implementation of 100%.

Research on plastic glazings has been driven by the polycarbonate (PC) industry in an effort to develop new markets for their products over the last 20 years. PC, which exhibits good optical clarity and excellent impact resistance, has recently been used in combination with commercial coatings for prototype or commercial low wear automotive components. Examples include moon roofs, quarter rear windows and tailgates. However, current PC glazings solutions still lack a certain level of performance, even for low wear areas. The main technical roadblocks are poor resistance to abrasion and to weathering, and high production cost. There have also been PMMA based solutions proposed. Compared to PC, PMMA is less expensive, exhibits better optical clarity, as well as better resistance to abrasion and to weathering but it is less resistant to impact and chemicals. Despite significant technological advances in polymer glazings, the following challenges remain objects to be addressed, for example, for large deployment and implementation: optical clarity, abrasion resistance (for example, for high wear areas such as windshields and moveable windows), safety (including impact resistance and fragmentation process), chemical resistance, weatherability, safety regulations and/or cost competitiveness.

Automotive glazing components desirably fulfil a number of requirements such as optical clarity, resistance to weathering, chemicals, scratches and abrasion as specified in ANSI/SAE Z26.1 as well as safety and cost competitiveness. The glazing systems further desirably meet or exceed regulatory requirements for driver visibility such as FMVSS 205, R43 and JIS R 3211 that have been stipulated in US, Europe and Japan respectively. Known commercial polymers without any coating protection do not meet all of these requirements.

Coating methods have been investigated that use wet coating and/or dry coating. For example, silicone-based wet coating and polysiloxane hard coating via plasma enhanced chemical vapor deposition methods (PECVD) on PC were developed and implemented in a modest number of vehicles but the products did not fully meet original equipment manufacturer (OEM) requirements. Another coating technology for PC required two steps of coating, a wet coating process in a separate system and a PECVD process in another system. However, this approach needs significant capital investment for both a wet coating process and a CVD process. As a potential replacement for PC, PMMA has received less attention. Wet coatings have been used to prepare PMMA that complies with the American National Standard for Safety Glazing Materials for Glazing Motor Vehicles and Motor Vehicle Equipment Operating on Land Highways (ANSI/SAE Z26.1). However, coating efficiency of vacuum-based coating technologies such as PECVD are currently low and need further improvement for PMMA in glazing applications.

Yang et al. have previously reported the fabrication of SiOₓ films by PECVD from a pure tetramethylorthosilicate (TMOS) precursor [see Yang, Mu-Rong Chen, Ko-Shao, Surface and Coatings Technology, 01/2000, Volume 123, Issue 2-3]. Hard, highly transparent, and highly adherent SiO₂ films were obtained by this process with a capacitively-coupled radio frequency (r.f.) (13.56 MHz) plasma system. With additional in situ Ar plasma post-treatment, the film properties were improved. The UV-VIS transmission spectra showed a high transmission of about 90% in the visible wavelength region, but reduced to zero in the UV region. The band gap of plasma TMOS-generated SiO₂ films was 3.8 eV on glass and 4.2 eV on PMMA. Hard coatings of SiO₂ deposited by plasma CVD on polycarbonate (PC) for automotive and optical applications have also been reported by Schmauder et al. [see Schmauder, T., Nauenburg, K.-D., Kruse, K., Ickes, G., (2006) Thin Solid Films, 502 (1-2), pp. 270-274.]. Other papers that reported deposition of SiO₂ and SiN hard coating on polycarbonate by plasma CVD (or plasma ion assisted deposition) include Zajičková et al. [see Zajičková, L., Buršiková, V., Janča, J., (1998) Vacuum, 50 (1-2), pp. 19-21.], Bergeron et al. [see Bergeron, A., Klemberg-Sapieha, J. E., Martinu, L., (1998) Journal of Vacuum Science and Technology A: Vacuum, Surfaces and Films, 16 (6), pp. 3227-3234] and Jakobs et al. [see Jakobs, S., Schulz, U., Duparré, A., Kaiser, N., (1997) Fresenius' Journal of Analytical Chemistry, 358 (1-2), pp. 242-244.].

There are also a number of patents and patent applications that have been published that report methods for preparing coatings for plastic glazing using vacuum based deposition methods. For instance, U.S. Pat. No. 8,236,383 B2 describes a method for the preparation of abrasion resistant plastic glazing with in-mold coating. Here, the abrasion resistant layer may be deposited by a vacuum deposition technique (e.g. PECVD etc.) and may be comprised of silicon monoxide, silicon dioxide, silicon nitride, silicon oxy-nitride, silicon oxy-carbide, hydrogenated silicon oxy-carbide, silicon carbide etc. US20080187725 teaches a plastic glazing for use in an automobile. The glazing includes a polycarbonate substrate, a conductive layer located adjacent to the polycarbonate substrate, and a glazing layer located adjacent to the conductive layer. The conductive layer comprises carbon nanotubes and the glazing layer is made of a material that is different from polycarbonate. The glazing layer includes at least one of an abrasion resistant layer and a weathering layer. A weathering material selected from the group consisting of polymethylmethacrylate, polysiloxane, polyurethane, and polycarbonate. An abrasion resistant material selected from the group consisting of silicon monoxide, silicon dioxide, silicon nitride, silicon oxy-nitride, silicon oxy-carbide, hydrogenated silicon oxy-carbide, silicon carbide etc. US 2007/0286966 A1 (EP2032390) teaches a method for applying an abrasion resistant layer via a vacuum deposition technique to a plastic automotive window. The deposition of the abrasion resistant sub-layers (e.g. SiOₓC_{y}H_{z}, oxide, fluoride, nitride and carbide by PECVD, sputtering) is carried out under controlled temperature conditions that reduce adhesion loss within the electroluminescent layer and maintains the electroluminescent functionality of that layer (From CN101522469 A). EP1429921 teaches an automotive glazing panel using a polycarbonate substrate having a coating system including an inner layer blocking IR (wet coat polythiophene compound-BAYTRON P) and overlying coating material blocking UV radiation (diorganodiorgonoxiysilane or organotriorganoxysilane-by sol-gel U.S. Pat. No. 6,376,064) and providing a scratch resistant outer coating layer (e.g. SiOₓC_{y}H_{z}, oxide, fluoride, nitride and carbide by PECVD). U.S. Pat. No. 6,110,544 A teaches a method for depositing adherent metal oxide-based protective coatings on glass, metal, and plastic substrates by arc plasma deposition. High-rate deposition of silicon oxide-based protective coatings on plastics such as polycarbonate by high rate arc plasma deposition is described therein. Polycarbonate pre-coated with about 4 to 8 microns of a silicone hardcoat were coated with silicon oxide-based using the plasma deposition method without direct cooling of the substrate. The patent described very few details of the high rate arc plasma deposition process to deposit silicon oxide.

### SUMMARY

A vacuum-based coating method using reactive magnetron sputtering under a “Closed Field” bipolar pulsed configuration or a combination of reactive magnetron sputtering under a “Closed Field” bipolar pulsed TwinMag sputtering configuration and plasma enhanced chemical vapor deposition was used to generate a scratch, abrasion and wear protective single layer AlSiN (or AlSiON) or dual layer AlSiN/SiOxCy coating on poly(methyl methacrylate) (PMMA). The reactive magnetron and PECVD process can advantageously be performed sequentially in the same chamber which may, for example, have lower capital investment and/or operation costs associated with it than a method comprising wet coating prior to CVD. The performance of the sputtering conditions was assessed and PMMA coated with the single layer AlSiN (or AlSiON) and the dual layer AlSiN/SiOₓC_{y} was assessed for surface morphology, optical transmittance, adhesion, and wear resistance.

Accordingly, the present application includes a method for preparing a coated substrate, the method comprising, depositing on the substrate by reactive magnetron sputtering, a single abrasion resistive layer.

Accordingly, the present application includes a method for preparing a coated substrate, the method comprising, depositing on the substrate, in either order:
by reactive magnetron sputtering, a first abrasion resistant layer; and
by plasma-enhanced chemical vapor deposition (PECVD), a second abrasion resistant layer.

The present application also includes a coated substrate prepared according to a method for preparing a coated substrate of the present application.

The present application further includes a coated substrate, comprising:
a substrate; and
a coating deposited on the substrate, the coating comprising a single abrasion resistant layer consisting essentially of or consisting of AlSiN (or AlSiON).

The present application further includes a coated substrate, comprising:
a substrate; and
a coating deposited on the substrate, the coating comprising, a first abrasion resistant layer consisting essentially of or consisting of AlSiN (or AlSiON) and a second abrasion resistant layer consisting essentially of or consisting of SiOₓC_{y}.

Other features and advantages of the present application will become apparent from the following detailed description. It should be understood, however, that the detailed description and the specific examples while indicating embodiments of the application are given by way of illustration only, since various changes and modifications within the spirit and scope of the application will become apparent to those skilled in the art from this detailed description.

### BRIEF DESCRIPTION OF THE DRAWINGS

The present application will now be described in greater detail with reference to the drawings in which:

FIG. 1 shows exemplary transmission spectra of poly(methyl methacrylate) (PMMA) treated with 30 W O₂ plasma (\textcircled{1}), 80 W O₂ plasma (\textcircled{3}), 30 W CO₂ plasma (\textcircled{4}) and 80 W CO₂ plasma (\textcircled{5}) in comparison to untreated PMMA (\textcircled{2}).

FIG. 2 shows exemplary transmission spectra of a AlSiN (or AlSiON) coating deposited by reactive magnetron sputtering (MS) on PMMA (*) in comparison to uncoated, untreated PMMA (**).

FIG. 3 is an exemplary scanning electron microscope (SEM) image of a SiOₓC_{y} coating deposited by PECVD on PMMA showing the locations of the energy-dispersive X-ray (EDX) spectra taken in Table 1. Scale bar at bottom of image indicates 10 μm.

FIG. 4 shows exemplary Dektak 3 Surface Profile measurement taken after Pin-on-disc wear tests using a steel ball at 100 mN force with 80 rpm rotation speed for 25 min wear time for a MS AlSiN coating deposited on PMMA substrate in comparison to uncoated, untreated PMMA.

FIG. 5 shows exemplary transmission spectra of a SiOₓC_{y} coating deposited by plasma-enhanced chemical vapor deposition (PECVD) on PMMA (*) in comparison to uncoated, untreated PMMA (**).

FIG. 6 is an exemplary SEM image of a SiOₓC_{y} coating deposited by PECVD on PMMA showing the locations of the EDX spectra taken in Table 2. Scale bar at bottom of image indicates 60 μm.

FIG. 7 shows exemplary transmission spectra of a SiOₓC_{y} coating deposited by PECVD on CO₂ plasma-(*) or O₂ plasma-(***) cleaned PMMA in comparison to uncoated, untreated PMMA (**).

FIG. 8 shows exemplary Dektak 3 Surface Profile measurement taken after Pin-on-disc wear tests using a steel ball at 100 mN force with 80 rpm rotation speed for 25 min wear time for a PECVD SiOxCy coating deposited on PMMA substrate in comparison to uncoated, untreated PMMA.

FIG. 9 shows exemplary transmission spectra of a PECVD SiOxCy coating, MS AlSiN coating, PECVD SiOxCy/MS AlSiN coatings and MS AlSiN/SiOxCy coating deposited on PMMA substrate in comparison to uncoated, untreated PMMA.

FIG. 10 shows exemplary Dektak 3 Surface Profile measurement taken after Pin-on-disc wear tests using a steel ball at 100 mN force with 80 rpm rotation speed for 25 min wear time for a PECVD SiOxCy/MS AlSiN coating deposited on PMMA substrate in comparison to uncoated, untreated PMMA.

FIG. 11 shows exemplary Dektak 3 Surface Profile measurement taken after Pin-on-disc wear tests using a steel ball at 100 mN force with 80 rpm rotation speed for 25 min wear time for a MS AlSiN/PECVD SiOxCy coating deposited on PMMA substrate in comparison to uncoated, untreated PMMA.

### DETAILED DESCRIPTION

### I. Definitions

Unless otherwise indicated, the definitions and embodiments described in this and other sections are intended to be applicable to all embodiments and aspects of the present application herein described for which they are suitable as would be understood by a person skilled in the art.

In understanding the scope of the present application, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. The term “consisting” and its derivatives, as used herein, are intended to be closed terms that specify the presence of the stated features, elements, components, groups, integers, and/or steps, but exclude the presence of other unstated features, elements, components, groups, integers and/or steps. The term “consisting essentially of”, as used herein, is intended to specify the presence of the stated features, elements, components, groups, integers, and/or steps as well as those that do not materially affect the basic and novel characteristic(s) of features, elements, components, groups, integers, and/or steps.

Terms of degree such as “substantially”, “about” and “approximately” as used herein mean a reasonable amount of deviation of the modified term such that the end result is not significantly changed. These terms of degree should be construed as including a deviation of at least ±5% of the modified term if this deviation would not negate the meaning of the word it modifies.

The term “and/or” as used herein means that the listed items are present, or used, individually or in combination. In effect, this term means that “at least one of” or “one or more” of the listed items is used or present.

As used in this application, the singular forms “a”, “an” and “the” include plural references unless the content clearly dictates otherwise.

The term “suitable” as used herein means that the selection of specific reagents or conditions will depend on the reaction being performed and the desired results, but none-the-less, can generally be made by a person skilled in the art once all relevant information is known.

The term “abrasion resistant layer” refers to the ability of a coating layer to withstand abrasion and means that the layer possess the ability to pass a test for abrasion resistance according to Military Specifications MIL-C-675C.

The term “blocking layer” as used herein in reference to an “ultraviolet blocking layer” means that the layer at least partially blocks radiation having wavelengths in the ultraviolet region. Similarly, the term “blocking layer” as used herein in reference to an “infrared blocking layer” means that the layer at least partially blocks radiation having wavelengths in the infrared region.

The term “transparent” as used herein in reference to a transparent thermoplastic means that the thermoplastic has a percent transmittance of at least 80% in a wavelength range of from about 380 nm to about 700 nm.

### II. Methods

A vacuum-based coating method using either reactive magnetron sputtering under a “Closed Field” bipolar pulsed TwinMag configuration or a combination of reactive magnetron sputtering under a TwinMag configuration and plasma enhanced chemical vapor deposition was used to generate a scratch, abrasion and wear protective single layer AlSiN (or AlSiON) or dual layer AlSiN (or AlSiON)/SiOₓC_{y} coating on poly(methyl methacrylate) (PMMA).

The reactive magnetron and PECVD process can advantageously be performed sequentially in the same chamber which may, for example, have lower capital investment and/or operation costs associated with it than a method comprising wet coating prior to CVD. The performance of the sputtering conditions was assessed and PMMA coated with the single layer AlSiN (or AlSiON) or the dual layer AlSiN/SiOₓC_{y} was assessed for surface morphology, optical transmittance, adhesion, and wear resistance.

Accordingly, the present application includes a method for preparing a coated substrate, the method comprising, depositing on the substrate, by reactive magnetron sputtering, a single abrasion resistant layer, or a dual layer in which a first abrasion resistant layer of the dual layer is deposited by magnetron sputtering.

In an embodiment, the method comprises: depositing on the substrate, by reactive magnetron sputtering, a single abrasion resistant.

In an embodiment, the method comprises: depositing on the substrate, in either order:
by reactive magnetron sputtering, the first abrasion resistant layer; and
by plasma-enhanced chemical vapor deposition (PECVD), a second abrasion resistant layer.

In an embodiment, the method comprises depositing a single abrasion resistant layer on the substrate.

In an embodiment, the method comprises
depositing the first abrasion resistant layer on the substrate; and
depositing the second abrasion resistant layer on the first abrasion resistant layer.

In an embodiment, the reactive magnetron sputtering is carried out in a TwinMag configuration. In another embodiment, the reactive magnetron sputtering comprises sputtering under a double magnetron cathode configuration in which two cathode bodies are inclined from the normal about 10-60° to face each other. In a further embodiment, the reactive magnetron sputtering under a “Closed Field” bipolar pulsed TwinMag sputtering configuration.

In an embodiment, the single layer or the first abrasion resistant layer in the dual layer comprises, consists essentially of or consists of a silicon-metal composite. In another embodiment, the single layer or the first abrasion resistant layer in the dual layer comprises a silicon-metal composite. In a further embodiment, the single layer or the first abrasion resistant layer in the dual layer consists essentially of a silicon-metal composite. In another embodiment, the single layer or the first abrasion resistant layer in the dual layer consists of a silicon-metal composite. In an embodiment, the metal in the silicon-metal composite is aluminum. In another embodiment, the silicon-metal composite is AlSiN (or AlSiON); for example, the single layer or the first abrasion resistant layer in the dual layer comprises, consists essentially of or consists of the AlSiN (or AlSiON).

In an embodiment, the second abrasion resistant layer in the dual layer comprises, consists essentially of or consists of SiOₓC_{y}. In another embodiment, the second abrasion resistant layer in the dual layer comprises SiOₓC_{y}. In a further embodiment, the second abrasion resistant layer in the dual layer consists essentially of SiOₓC_{y}. In another embodiment of the present application, the second abrasion resistant layer in the dual layer consists of SiOₓC_{y}.

In an embodiment, the first abrasion resistant layer in the dual layer consists essentially of or consists of AlSiN (or AlSiON) and the second abrasion resistant layer in the dual layer consists essentially of or consists of SiOₓC_{y}. In another embodiment of the present application, the first abrasion resistant layer in the dual layer consists essentially of AlSiN and the second abrasion resistant layer in the dual layer consists essentially of SiOₓC_{y}. In a further embodiment, in the dual layer the first abrasion resistant layer consists of AlSiN and the second abrasion resistant layer consists of SiOₓC_{y}.

In an embodiment, prior to deposition, the substrate is treated with a radio frequency (RF) plasma. The treatment with the RF plasma can comprise any suitable conditions. For example, in the examples of the present application it was found that treatment of transparent thermoplastic PMMA with high energy (80 W) plasma in a Diener plasma surface cleaning system type FEMTO resulted in the yellowing of the samples and treatment of PMMA with Ar/O₂ plasma was found to result in oxidation of the PMMA which may reduce coating adhesion. Therefore if the substrate comprises, for example, PMMA or a similar material, the person skilled in the art desirably selects a lower power plasma that will not oxidize the PMMA. Accordingly, in another embodiment, the RF plasma is an Ar/CO₂ or Ar/N₂ plasma has a power that is sufficiently high enough to remove surface contamination and not induce polymer oxidation and/or decrease the transparency less than 10% or less than 5%, such as but not limited to a power of from about 10 W to about 100 W, about 25 W to about 35 W or about 30 W. It should be noted that the power suitable depends on, for example but not limited to, the type of plasma cleaner used and the size of polymer substrate.

The substrate is any suitable substrate. In an embodiment, the substrate comprises, consists essentially of or consists of a plastic or a glass. In an embodiment, the substrate comprises, consists essentially of or consists of a transparent thermoplastic. In another embodiment, the substrate comprises a transparent thermoplastic. In a further embodiment, the substrate consists essentially of a transparent thermoplastic. In another embodiment of the present application, the substrate consists of a transparent thermoplastic. In an embodiment, the transparent thermoplastic is selected from a polycarbonate, a poly(methyl methacrylate) or the like. In another embodiment, the transparent thermoplastic is poly(methyl methacrylate); for example, the substrate comprises, consists essentially of or consists of the poly(methyl methacrylate).

In an embodiment, the substrate is an automotive glazing component. In another embodiment, the automotive glazing component is selected from a moon roof, a window, a windshield and a tailgate.

In an embodiment, the reactive magnetron sputtering and the PECVD are performed sequentially in the same chamber.

In an embodiment, the method further comprises depositing one or more additional coating layers. For example, in an embodiment, the method further comprises depositing one or more ultraviolet (UV) and/or infrared (IR) blocking layers. In an embodiment, the UV blocking layer comprises, consists essentially of or consists of ZnO, TiO₂ or combinations thereof. In another embodiment, the IR blocking layer comprises, consists essentially of or consists of indium tin oxide (ITO), aluminum-doped zinc oxide (AZO), silver or combinations thereof. In an embodiment, the UV and/or IR blocking layers are deposited on the substrate prior to the deposition of the abrasion resistant layers. In another embodiment, the UV and/or IR blocking layers are deposited by a method comprising reactive magnetron sputtering, PECVD or combinations thereof.

In an embodiment, the method further comprises depositing a superhydrophobic layer on the abrasion resistant layers.

In an alternative embodiment, the method does not comprise the deposition of additional coating layers.

The present application also includes a coated substrate prepared according to a method for preparing a coated substrate of the present application.

### III. Coated Substrates

A scratch, abrasion and wear protective single layer AlSiN (or AlSiON) or a dual layer AlSiN (or AlSiON)/SiOₓC_{y} coating on poly(methyl methacrylate) (PMMA) was obtained from a vacuum-based coating method that used a combination of reactive magnetron sputtering under a TwinMag configuration and plasma enhanced chemical vapor deposition. PMMA coated with the single layer AlSiN (or AiSiON) or the dual layer AlSiN (or AlSiON)/SiOₓC_{y} was assessed for surface morphology, optical transmittance, adhesion, and wear resistance.

Accordingly, the present application includes a coated substrate, comprising:
a substrate; and
a coating deposited on the substrate, the coating comprising, a single layer AlSiN (or AiSiON) or a dual layer, in either order, a first abrasion resistant layer consisting essentially of or consisting of AlSiN (or AlSiON) and a second abrasion resistant layer consisting essentially of or consisting of SiOₓC_{y}.

In some embodiments, the coated substrate is prepared according to a method for preparing a coated substrate of the present application.

In an embodiment of the present application, the first abrasion resistant layer in the dual layer is deposited on the substrate and the second abrasion resistant layer in the dual layer is deposited on the first abrasion resistant layer.

In an embodiment, the first abrasion resistant layer in the dual layer consists essentially of the AlSiN (or AlSiON) and the second abrasion resistant layer consists essentially of the SiOₓC_{y}. In another embodiment, the first abrasion resistant layer in the dual layer consists of the AlSiN (or AlSiON) and the second abrasion resistant layer consists of the SiOₓC_{y}.

In an embodiment, prior to deposition, the substrate has been treated with a radio frequency (RF) plasma. The treatment with the RF plasma can comprise any suitable conditions. Accordingly, in another embodiment, the RF plasma is an Ar/CO₂ or Ar/N₂ plasma having a power of from about 10 W to about 100 W for a piece of 25 cm² plastic substrate in a Diener plasma surface cleaning system type FEMTO, about 25 W to about 35 W or about 30 W.

The substrate is any suitable substrate. In an embodiment, the substrate comprises, consists essentially of or consists of a plastic or a glass. In an embodiment, the substrate comprises, consists essentially of or consists of a transparent thermoplastic. In another embodiment, the substrate comprises a transparent thermoplastic. In a further embodiment, the substrate consists essentially of a transparent thermoplastic. In another embodiment of the present application, the substrate consists of a transparent thermoplastic. In an embodiment, the transparent thermoplastic is selected from a polycarbonate, a poly(methyl methacrylate) or the like. In another embodiment, the transparent thermoplastic is poly(methyl methacrylate); for example, the substrate comprises, consists essentially of or consists of the poly(methyl methacrylate).

In an embodiment, the substrate is an automotive glazing component. In another embodiment, the automotive glazing component is selected from a moon roof, a window, a windshield and a tailgate.

In an embodiment, the coating further comprises one or more additional coating layers. For example, in an embodiment, the coated substrate further comprises one or more ultraviolet (UV) and/or infrared (IR) blocking layers. In an embodiment, the UV blocking layer comprises, consists essentially of or consists of ZnO, TiO₂ or combinations thereof. In another embodiment, the IR blocking layer comprises, consists essentially of or consists of indium tin oxide (ITO), aluminum-doped zinc oxide (AZO), silver or combinations thereof. In an embodiment, the UV and/or IR blocking layers are between the substrate and the abrasion resistant layers. In another embodiment, the coated substrate further comprises a superhydrophobic layer deposited on the abrasion resistant layers.

In an alternative embodiment, the coating does not comprise additional coating layers; i.e. it is devoid of additional coating layers.

The following non-limiting examples are illustrative of the present application:

### EXAMPLES

### Example 1: Surface Pre-Treatment of PMMA with CO₂, N₂ and O₂ Plasma

For substrate surface cleaning and with an object of coating adhesion improvement, various radio frequency (RF) plasma conditions were investigated for use to treat PMMA samples.

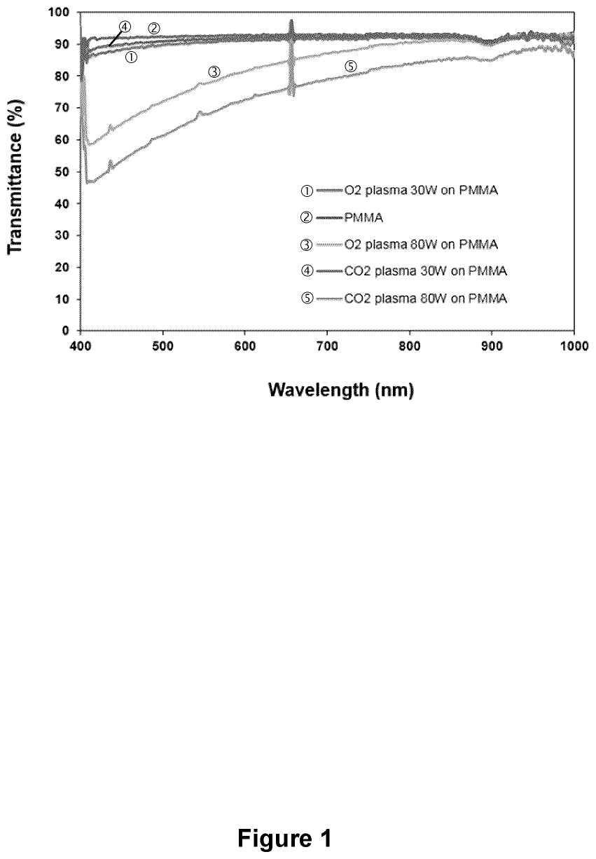

PMMA samples were treated with O₂/Ar and CO₂/Ar plasma at 30 and 80 W for 20 minutes in a Diener plasma surface cleaning system type FEMTO. The samples treated with 80 W plasma were observed to have a yellow appearance. A transmission spectrum (FIG. 1) showed significant differences between the PMMA samples treated with 80 W plasma and the untreated PMMA/PMMA samples treated with only 30 W plasma.

### Example 2: AlSiN (or AlSiON) on PMMA

Reactive magnetron sputtering under “Closed Field” bipolar pulsed TwinMag configuration was used to deposit AlSiN (or AlSiON) coatings on PMMA samples using a Si and an Al metallic targets under Ar/N₂ reactive gas. Before the deposition, pre-treatment of the PMMA thermoplastic by gas plasma in vacuum with low partial pressure was used in order to clean the substrate and improve the adhesion between the PMMA substrate and the coating material.

Single layers of AlSiN (or AlSiON) by sputtering were deposited on the PMMA substrate as described below.

### I. Deposition Process—Magnetron Sputtering of AlSiN on PMMA Substrates

The deposition equipment used in the examples described herein can be described as home-made sputtering with two different magnetron guns with opposite magnetic poles purchased from Kurt J. Lesker Company in a con-focal geometry. In this configuration, the magnetron sputter guns, which can host targets of two-inch in diameter, were 45° tilted and located 10 cm off-axis of the substrate. The AlSiN thin films were deposited at room temperature onto 10×10 cm² PMMA substrates by reactive magnetron sputtering from a 99.99% purity Al and Si target using a AE PE II 5 KW power supply that provided a 90 W and 40 kHz resonant switch-mode power dual (floating) outputs to each sputtering gun. Before each deposition process, the PMMA substrate to be used was washed with liquid soap and then deionized water. The PMMA substrate was then rinsed first with abundant deionized water and subsequently dried with nitrogen gas and placed on the holder-plate inside the sputtering chamber. An Ar/N₂ gas mixture was then introduced into the vacuum chamber to reach around 30 mtorr pressure. An AC voltage of 140V at 35 KHz from a Solvix® pulsed-DC power supply was applied on the substrate holder to generate a plasma to clean the PMMA substrate for around 2 hours.

The distance from the center of the target to the center of the substrate was around 5-7 cm, and a substrate rotation of 900 counts/sec was used to achieve a good homogeneity during the material deposition. The base pressure achieved before deposition was always between 2×10⁻⁷ Torr and 4.0×10⁻⁷ Torr, which were measured with an ionization vacuum gauge. The working gas was 99.99% argon and nitrogen. The DC power values of 80 W were used; these values correspond, when divided by the target area (20.27 cm²), to the power densities of 3.94 W/cm². The deposition pressure values were around 7.0 mTorr; these pressure values were manually adjusted while maintaining argon and nitrogen flow constant with a value of 104 sccm and 100 sccm, respectively.

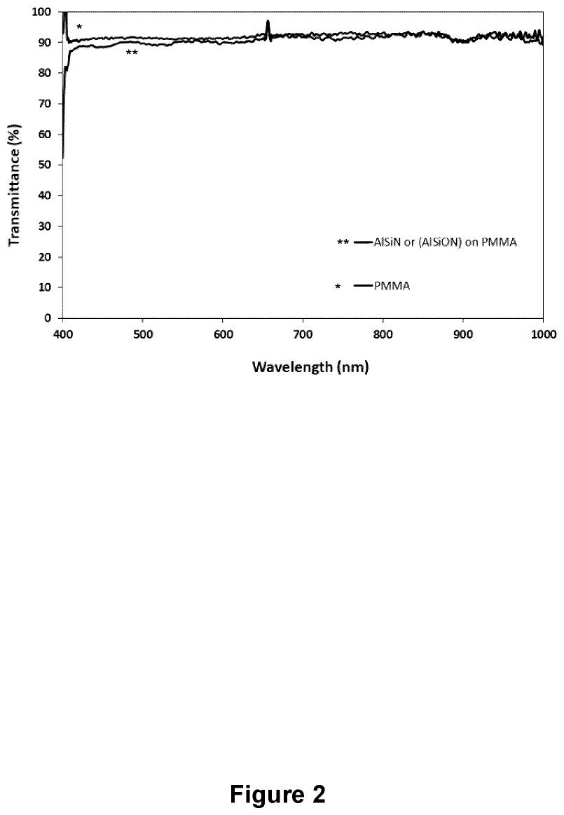

The thickness of an exemplary AlSiN (or AlSiON) coating was determined by a Bruker Dektak™ profilometer to be 230 nm. A FilmTek™ 3000 photospectrometer was used to measure the thin film transmittance in comparison to uncoated PMMA (FIG. 2).

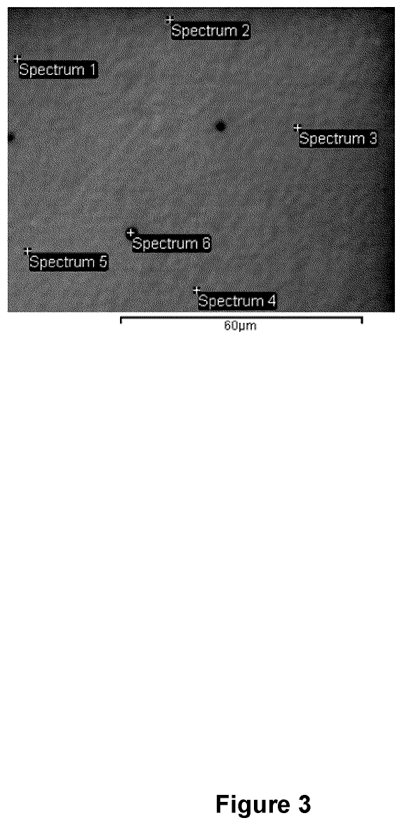

Table 1 and FIG. 3 are energy-dispersive X-ray (EDX) spectroscopy data and the SEM image clearly showing an AlSiN (AlSiON) film was deposited on the PMMA. Please noted that N element cannot be detected by the EDX method. C element originated from the oxy-carbon surface species generated after the coatings were exposed to ambient air.

TABLE 1
EDX spectroscopy data showing an AlSiN
(AlSiON) film deposited on the PMMA

| | C | O | Al | Si |
|---|---|---|---|---|
| Spectrum # | (atomic %) | (atomic %) | (atomic %) | (atomic %) |
| Spectrum 1 | 20.44 | 36.52 | 18.78 | 24.26 |
| Spectrum 2 | 23.33 | 34.42 | 18.29 | 23.97 |
| Spectrum 3 | 25.23 | 34.94 | 17.14 | 22.69 |
| Spectrum 4 | 23.82 | 35.05 | 17.56 | 23.57 |
| Spectrum 5 | 24.89 | 35.12 | 17.15 | 22.83 |
| Spectrum 6 | 56.49 | 21.34 | 9.63 | 12.54 |
| Mean | 28.42 | 32.88 | 16.63 | 22.06 |
| Std. deviation | 11.73 | 4.86 | 2.98 | 4.00 |
| Max. | 56.49 | 36.52 | 18.78 | 25.12 |
| Min. | 20.44 | 21.34 | 9.63 | 12.54 |

Adhesion was tested according to Military Specifications MIL-C-675C. Briefly, a ½″ wide strip of cellophane tape was pressed against the coated surface and quickly removed. The AlSiN (or AlSiON) coated PMMA sample passed the test; no delamination was observed. Abrasion resistance was also tested according to Military Specifications MIL-C-675C: In particular, for moderate abrasion, the coated sample was rubbed with a cheese cloth pad for 25 cycles (50 strokes) and for severe abrasion, a MIL-E-12397 compliant eraser was rubbed over the coated surface for 20 complete cycles (40 strokes). The AlSiN (or AlSiON) coated PMMA sample passed the test; no delamination was observed.

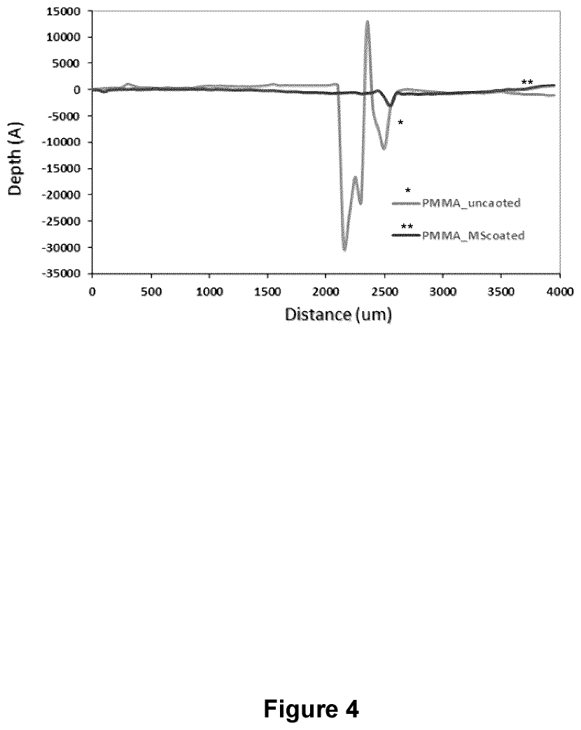

FIG. 4 shows exemplary Dektak 3 Surface Profile measurement taken after Pin-on-disc wear tests using a steel ball at 100 mN force with 80 rpm rotation speed for 25 min wear time for a MS AlSiN (or AlSiON) coating deposited on PMMA substrate in comparison to uncoated, untreated PMMA.

In summary, reactive magnetron sputtering with “Closed Field” bipolar pulsed TwinMag configuration was able to deposit transparent AlSiN (or AlSiON) films on PMMA substrates which had useful adhesive and abrasion resistance properties.

### Example 3: SiOₓC_{y} Coatings on PMMA

Plasma-enhanced chemical vapor deposition (PECVD) was used to deposit SiOₓC_{y} coatings on PMMA samples using a hexamethyldisiloxane (HMDS) precursor. Before the deposition, pre-treatment of the PMMA thermoplastic by gas plasma in vacuum with low partial pressure was used in order to clean the substrate and improve the adhesion between the PMMA substrate and the coating material.

Single layers of SiOₓC_{y} (by PECVD) were deposited on the PMMA substrate as described below.

II. Deposition Process—PECVD Coating of SiOₓC_{y} on PMMA Substrates

The deposition unit used for depositing SiOₓC_{y} thin films on PMMA substrates was built by Plasmionique Inc. and was modified to produce PECVD coatings by using liquid precursors. The carbon-based coating was a composite structure comprised of the elements C, H, Si and O. The precursor used was a carbon-containing and silicon-containing liquid precursor such as hexamethyldisiloxane. Hexamethyldisilazane can replace hexamethyldisiloxane as liquid precursor. Hexamethyldisilazane contains N instead of O along with the other the elements C, H, and Si. When hexamethyldisilazane is used as precursor, a deposit of SiNₓC_{y} thin films is obtained which has similar protective properties as SiOₓC_{y} thin films. If needed, the oxygen can be added as a gas during deposition process. Other precursors (hydrocarbon, silane, organosilane, organosilazane, etc.), or mixtures containing similar chemical elements, may also be used but were not tested in these experiments. The thin-film material was obtained by ion-assisted plasma deposition using radio frequency decomposition of liquid precursors. The deposition was conducted at room temperature on 10×10 cm² PMMA substrates. Radio-frequency plasma was generated in a capacitive mode, on the substrate holder, by using an RF power supply with a frequency of 13.6 MHz. Before each deposition process, the PMMA substrate was washed with liquid soap, rinsed with abundant water, dried using a compressed air gun and then placed on the substrate holder inside the deposition chamber. The vacuum system was started and Ar gas with a flow of 20 sccm was introduced into the vacuum chamber to reach a pressure of 20 mTorr. RF plasma was generated on the substrate, with a power of 20 W, for 20 minutes, for cleaning the PMMA substrate. After plasma cleaning, without stopping the RF plasma, the thin film growth was initiated by introducing the liquid precursor with a flow rate of 5 g/h. After introducing the liquid precursor, the deposition pressure increased to 25 mTorr. After deposition (30-60 minutes), the plasma, the liquid precursor, and the Ar flow was stopped and the chamber was vented to atmospheric pressure. The substrate was removed from the chamber being ready for testing. The thickness of the thin film obtained after a deposition process of 60 minutes was around 10 microns.

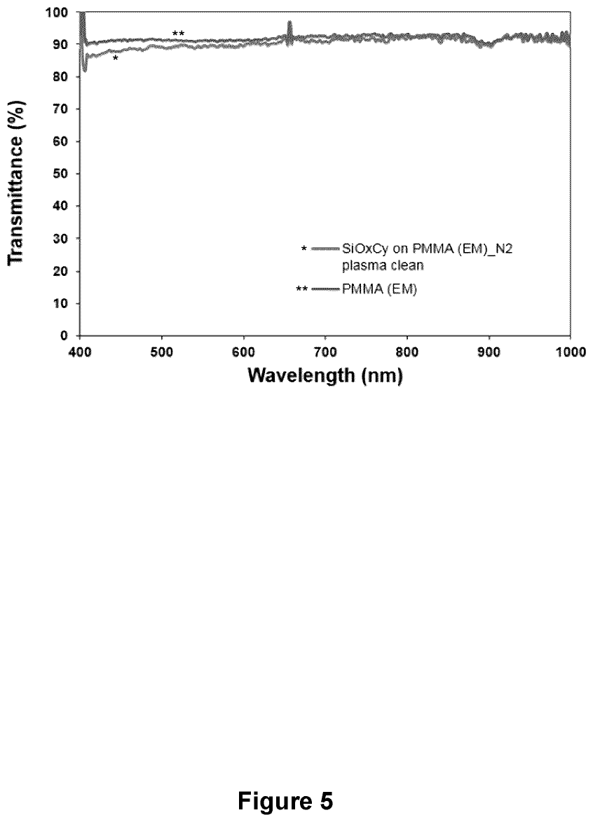

The thickness of an exemplary SiOₓC_{y} coating was determined by a Bruker Dektak™ profilometer to be 2.2 μm. A FilmTek™ 3000 photospectrometer was used to measure the thin film transmittance in comparison to uncoated PMMA (FIG. 5).

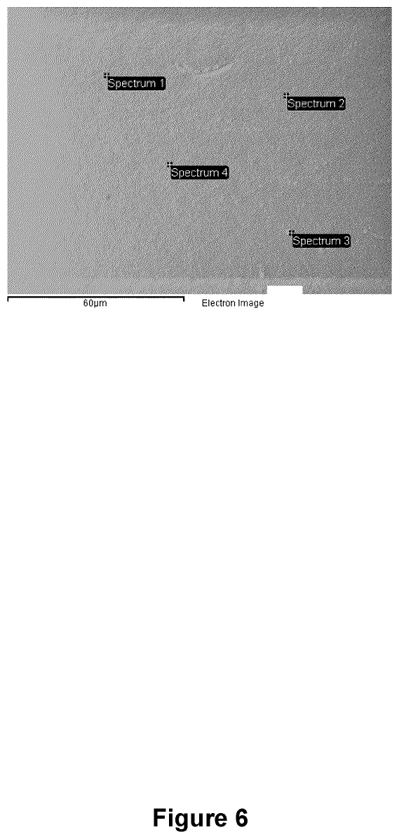

Table 2 and FIG. 6 are energy-dispersive X-ray (EDX) spectroscopy data and the SEM image clearly showing a SiOₓC_{y} film was deposited on the PMMA.

TABLE 2
EDX spectroscopy data showing
a SiOₓC_{y} film deposited on PMMA

| Spectrum No. | C (atomic %) | O (atomic %) | Si (atomic %) |
|---|---|---|---|
| 1 | 50.17 | 23.33 | 26.50 |
| 2 | 55.67 | 21.99 | 22.34 |
| 3 | 55.55 | 21.25 | 23.19 |
| 4 | 57.46 | 21.07 | 21.47 |
| Mean | 54.71 | 21.91 | 23.38 |
| Std. deviation | 3.15 | 1.03 | 2.20 |
| Max. | 57.46 | 23.33 | 26.50 |
| Min. | 50.17 | 21.07 | 21.47 |

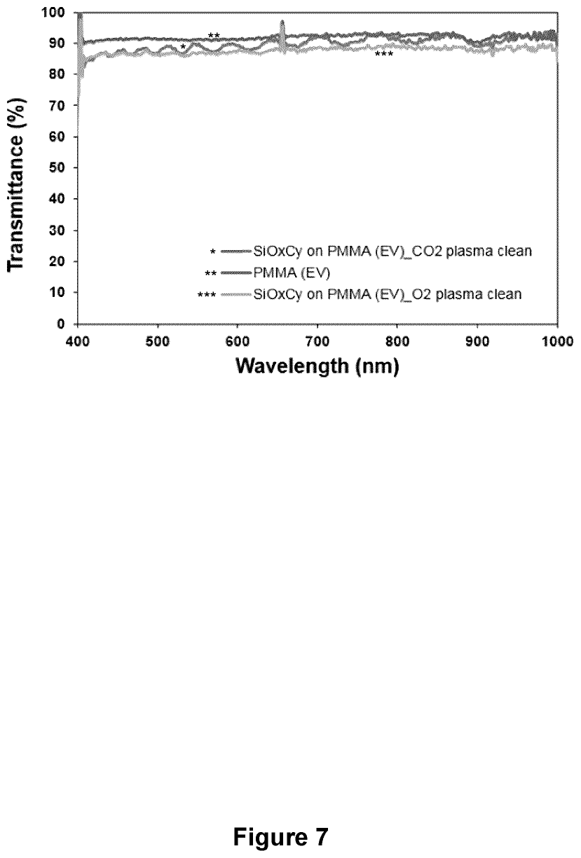

Adhesion was tested according to Military Specifications MIL-C-675C. Briefly, a ½″ wide strip of cellophane tape was pressed against the coated surface and quickly removed. The SiOₓC_{y} coated PMMA sample passed the test; no delamination was observed. Abrasion resistance was also tested according to Military Specifications MIL-C-675C: In particular, for moderate abrasion, the coated sample was rubbed with a cheese cloth pad for 25 cycles (50 strokes) and for severe abrasion, a MIL-E-12397 compliant eraser was rubbed over the coated surface for 20 complete cycles (40 strokes). The SiOₓC_{y} coated PMMA sample passed the test; no delamination was observed. SiOₓC_{y} was coated on PMMA (film thickness 2.1 μm) which was pre-cleaned with CO₂ plasma versus O₂ plasma. A transmission spectrum of these coated samples in comparison to uncoated, untreated PMMA is shown in FIG. 7. The SiOₓC_{y} film on CO₂ plasma pre-cleaned PMMA passed the adhesion test and film cracking was not observed. In contrast, the SiOₓC_{y} film on O₂ plasma pre-cleaned PMMA did pass the adhesion test but the film had cracking/particles. While not wishing to be limited by theory, the O₂ plasma surface pre-treatment oxidizes PMMA and thereby reduces the coating adhesion.

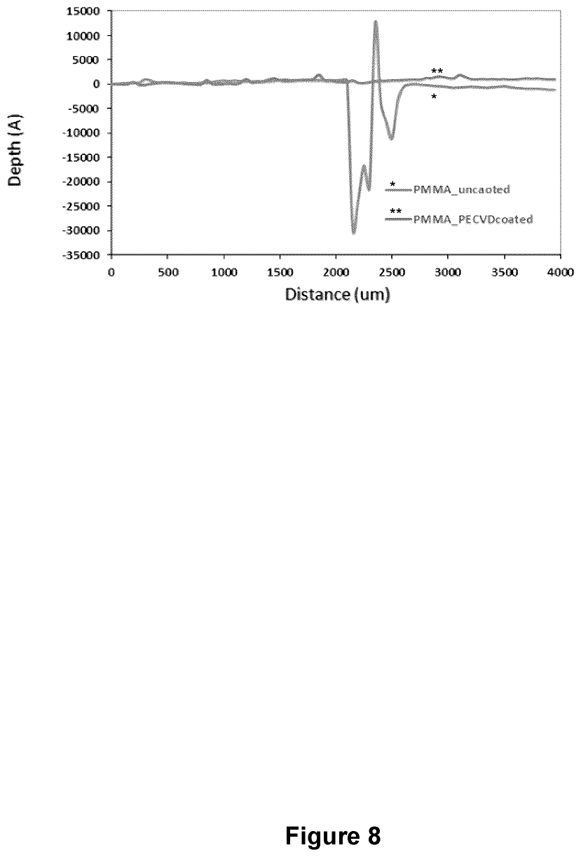

FIG. 8 shows exemplary Dektak 3 Surface Profile measurement taken after Pin-on-disc wear tests using a steel ball at 100 mN force with 80 rpm rotation speed for 25 min wear time for a PECVD SiOxCy coating deposited on PMMA substrate in comparison to uncoated, untreated PMMA.

In summary, PECVD with a RF bottom configuration was able to deposit transparent SiOₓC_{y} films on N₂ or CO₂ plasma treated PMMA substrates which had useful adhesive and abrasion resistance properties.

### Example 4: Deposition of Dual Layer AlSiN (or AlSiON)/SiOxCy or SiOxCy/AlSiN (or AlSiON) Protective Coatings on PMMA

Reactive magnetron sputtering under a double magnetron cathode (TwinMag) configuration in which two cathode bodies inclined from the normal (10-30°) to face each other (TwinMag) and plasma enhanced chemical vapor deposition (PECVD) were used to deposit dual layer protective coatings on poly(methyl methacrylate) (PMMA). Before the deposition, pre-treatment of the PMMA thermoplastic by gas plasma in vacuum with low partial pressure was used in order to clean the substrate and improve the adhesion between the PMMA substrate and the coating material.

A dual layer of AlSiN (or AlSiON)/SiOxCy (by combined sputtering/PECVD) was deposited on the PMMA substrate. The methods for the deposition of the layer of AlSiN (or AlSiON) by sputtering and the layer of SiOxCy by PECVD were described above in example 2 and 3.

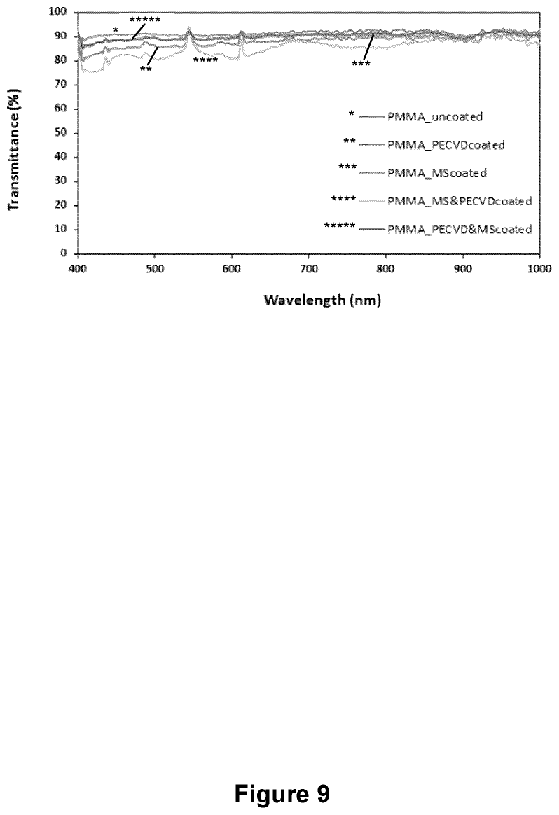

FIG. 9 shows exemplary transmission spectra of a PECVD SiOxCy coating, MS AlSiN (or AlSiON) coating, PECVD SiOxCy/MS AlSiN (or AlSiON) coatings and MS AlSiN (or AlSiON)/PECVD SiOxCy coating deposited on PMMA substrate in comparison to uncoated, untreated PMMA.

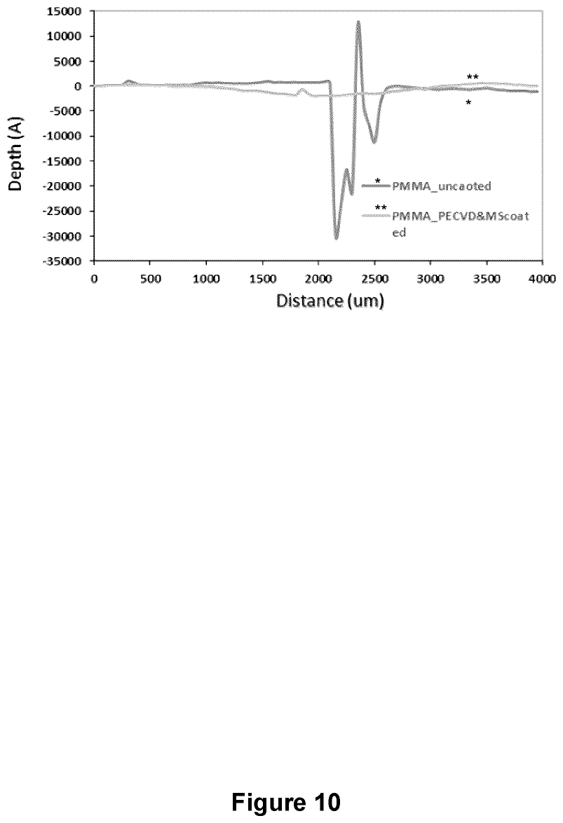

FIG. 10 shows exemplary Dektak 3 Surface Profile measurement taken after Pin-on-disc wear tests using a steel ball at 100 mN force with 80 rpm rotation speed for 25 min wear time for a PECVD SiOxCy/MS AlSiN (or AlSiON) coating deposited on PMMA substrate in comparison to uncoated, untreated PMMA.

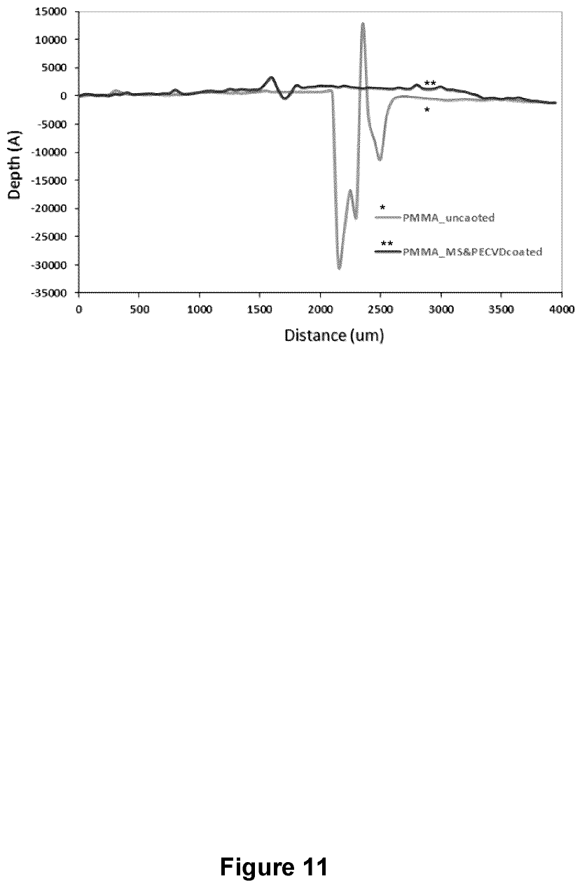

FIG. 11 shows exemplary Dektak 3 Surface Profile measurement taken after Pin-on-disc wear tests using a steel ball at 100 mN force with 80 rpm rotation speed for 25 min wear time for a MS AlSiN (or AlSiON)/PECVD SiOxCy coating deposited on PMMA substrate in comparison to uncoated, untreated PMMA.

### RESULTS AND DISCUSSION

The performance of the sputtering, PECVD and combined sputtering/PECVD coated PMMA thermoplastics were assessed for their surface morphologies, optical transmittance, adhesion, and wear resistance and they all showed significant improvement in wear, scratch and abrasion resistance compared to bare PMMA and maintained high transparency to visible light (>85%). With this coating method, other functionalities can also be added to the plastic such as a UV- or IR-blocking layer and/or a hydrophobic layer.

Such coatings may, for example, be useful in the development of lightweight automotive polymer glazings that may reduce weight by up to about 50% compared to current glass glazings as the coated thermoplastics such as PMMA may have potential to replace tempered glass or laminated glass.

While the present application has been described with reference to what are presently considered to be the preferred examples, it is to be understood that the application is not limited to the disclosed examples. To the contrary, the present application is intended to cover various modifications and equivalent arrangements included within the spirit and scope of the appended claims.

All publications, patents and patent applications are herein incorporated by reference in their entirety to the same extent as if each individual publication, patent or patent application was specifically and individually indicated to be incorporated by reference in its entirety. Where a term in the present application is found to be defined differently in a document incorporated herein by reference, the definition provided herein is to serve as the definition for the term.

1. A method for preparing a coated substrate, the method comprising:
depositing on the substrate,
a single abrasion resistant layer by reactive magnetron sputtering; or
a dual layer including a first abrasion resistant layer deposited by reactive magnetron sputtering and a second abrasion resistant layer deposited by plasma-enhanced chemical vapor deposition (PECVD).

2. The method of claim 1, wherein, for the dual layer, the method comprises:
depositing the first abrasion resistant layer on the substrate; and
depositing the second abrasion resistant layer on the first abrasion resistant layer.

3. The method of claim 1, wherein the reactive magnetron sputtering comprises sputtering under a double magnetron cathode configuration in which two cathode bodies are inclined from the normal about 10-60o to face each other.

4. The method of claim 1, wherein the reactive magnetron sputtering is a “Closed Field” bipolar pulsed TwinMag sputtering configuration.

5. The method of claim 1, wherein, the single abrasion resistant layer or the first abrasion resistant layer of the dual layer comprises AlSiN.

6. The method of claim 1, wherein the second abrasion resistant layer in the dual layer comprises SiOxCy.

7. The method of claim 1, wherein the dual layer is deposited on the substrate and the first abrasion resistant layer comprises AlSiN or AlSiON and the second abrasion resistant layer comprises SiOxCy.

8. The method of claim 1, wherein prior to deposition, the substrate is treated with a radio frequency (RF) plasma.

9. The method of claim 8, wherein the RF plasma is an Ar/CO2 or Ar/N2 plasma having a power that is sufficiently high enough to remove surface contamination and not induce polymer oxidation and/or decrease the transparency less than 10% or less than 5%.

10. The method of claim 1, wherein the substrate comprises a material selected from: a transparent thermoplastic, poly(methyl methacrylate) or polycarbonates.

11. (canceled)

12. The method of claim 1, wherein the substrate is an automotive glazing component selected from a moon roof, a window, a windshield and a tailgate.

13. (canceled)

14. The method of claim 1, wherein for the dual layer the reactive magnetron sputtering and the PECVD are performed sequentially in the same chamber.

15. (canceled)

16. A coated substrate, comprising:
a substrate; and
a coating deposited on the substrate, the coating comprising, a single abrasion resistant layer, or a dual layer comprising, in either order, a first abrasion resistant layer comprising AlSiN or AlSiON and a second abrasion resistant layer comprising SiOxCy.

17. The coated substrate of claim 16, wherein for the dual layer the first abrasion resistant layer is deposited on the substrate and the second abrasion resistant layer is deposited on the first abrasion resistant layer.

18. The coated substrate of claim 16, wherein prior to deposition, the substrate has been treated with a radio frequency (RF) plasma.

19. The coated substrate of claim 18, wherein the RF plasma is an Ar/CO₂ or Ar/N₂ plasma having a power that is sufficiently high enough to remove surface contamination and not induce polymer oxidation and/or decrease the transparency less than 10% or less than 5% T.

20. The coated substrate of claim 16, wherein the substrate comprises a material selected from: a transparent thermoplastic, poly(methyl methacrylate) or polycarbonates.

21. The coated substrate of claim 16, wherein the substrate comprises poly(methyl methacrylate) polycarbonates.

22. The coated substrate of claim 16, wherein the substrate is an automotive glazing component selected from a moon roof, a window, a windshield or a tailgate.

23. (canceled)
